(19) United States
(12) Patent Application Publication
(10) Pub. No.: US 2004/0217333 A1
(43) Pub. Date: Nov. 4, 2004

(54) N-type thermoelectric material and method of preparing thereof

(75) Inventors: Norihiko Miyashita, Saitama (JP); Tomoyasu Yano, Saitama (JP); Ryoma Tsukuda, Saitama (JP); Isamu Yashima, Saitama (JP)

Correspondence Address: SUGHRUE MION, PLLC, 2100 PENNSYLVANIA AVENUE, N.W., SUITE 800, WASHINGTON, DC, 20037, US

(73) Assignee: MITSUI MINING & SMELTING CO., LTD.

(21) Appl. No.: 10/682,426

(22) Filed: Oct. 10, 2003

(30) Foreign Application Priority Data
Oct. 11, 2002 (JP) 2002-299565

(51) Int. Cl. B22F 1/00; H01L 35/30

(52) U.S. Cl. 252/500; 419/49

(57) ABSTRACT

A method of preparing an n-type thermoelectric material includes forming an alloyed ingot by mixing and melting a dopant to be added optionally and at least two elements selected from the group consisting of bismuth, tellurium, selenium, antimony, and sulfur to obtain a material mixture, and by cooling the material mixture. The method also includes pulverizing the alloyed ingot to obtain pulverized powder; sintering the pulverized powder at normal pressure to obtain a half sintered body; and subjecting the half sintered body to hot press performed at pressure more than the normal pressure.

### CROSS-REFERENCE TO RELATED APPLICATION

This application claims the benefit of the priority of Japanese Patent Application No. 2002-299565, filed on Oct. 11, 2002, and the disclosure of the application is incorporated by reference herein in its entirety.

### BACKGROUND OF THE INVENTION

1) Field of the Invention

The present invention relates to an n-type thermoelectric material to be used as a material for a thermoelectric element using the Peltier effect or Seebeck effect and a method of preparing the n-type thermoelectric material, and more particularly, to an n-type thermoelectric material greatly improved in figure of merit, which is attained by accelerating the growth of crystallite but also enhancing the degree of sintering.

2) Description of the Related Art

The thermoelectric element using the Peltier effect or Seebeck effect can be employed in a wide variety of uses such as heating and cooling devices, temperature controlling devices, and thermoelectric electricity generators.

The performance of a thermoelectric material used as a material for a thermoelectric element is evaluated by the figure of merit, Z [K⁻¹], derived from the following equation (1):

Z=α²/(ρ·κ) (1)

where α[V·K⁻¹] is the Seebeck coefficient, κ[W·m⁻¹·K⁻¹] is the thermal conductivity, and ρ[Ω·m] is the resistivity.

The larger the figure of merit Z obtained by the equation (1), the higher the performance of a thermoelectric material. To increase the performance of the thermoelectricity material, in other words, to increase the figure of merit Z, it is necessary to increase the Seebeck coefficient and decrease not only the resistivity ρ but also the thermal conductivity κ.

Furthermore, the power factor PF [W·m⁻¹·K⁻²] of the thermoelectric material can be expressed by the following equation (2):

PF=α²/ρ (2)

where α is the Seebeck coefficient and ρ is the resistivity.

The resistivity ρ is inversely proportional to the product of the electron mobility μ [cm²·V⁻¹·s⁻¹] and the carrier density n [×10¹⁹ cm⁻³] within the crystal constituting the thermoelectric material. Therefore, to decrease the resistivity ρ, not only the mobility μ but also the carrier density n must be increased.

The Seebeck coefficient α is a function of the carrier density n. With an increase of the carrier density n, the Seebeck coefficient decreases. In other words, in order to increase the Seebeck coefficient, the carrier density n must be decreased.

However, since the carrier density n is inversely proportional to the resistivity ρ, as described above, the resistivity ρ increases as the carrier density n decreases. Therefore, there is the optimal carrier density n at which the Seebeck coefficient α is sufficiently large and the resistivity ρ is sufficiently small.

From the equations (1) and (2), it is presumed that the figure of merit Z and the power factor PF are in a proportional relationship. To describe more specifically, in order to increase the figure of merit Z, the power factor PF must be increased by increasing the mobility μ.

On the other hand, it is known that a p-type or n-type thermoelectric material obtained by adding an appropriate dopant to an alloy, which is represented by a general formula, (Bi, Sb)₂(Te, Se, S)₃, containing at least two elements selected from the group consisting of bismuth (Bi), tellurium (Te), selenium (Se), antimony (Sb), and sulfur (S), has a high figure of merit.

Such an n-type thermoelectric material is manufactured by a process that includes the steps of weighing out a material such as Bi, Te, Se, Sb or S, and a dopant in predetermined amounts, mixing and melting them to obtain an alloyed ingot, pulverizing the alloyed ingot into alloyed powder, and sintering the alloyed powder at normal pressure (normal-pressure sintering) to obtain a sintered body (see, for example, Japanese Patent Application Laid-Open No. 2001-313426).

Another process for manufacturing an n-type thermoelectric material includes the steps of weighing out a material such as Bi, Te, Se, Sb or S, and a dopant in predetermined amounts, mixing and melting them to obtain an alloyed ingot, pulverizing the alloyed ingot into alloyed powder, and subjecting the alloyed powder into hot-press sintering performed at a pressure higher than atmospheric normal pressure in place of subjecting to the normal pressure sintering, thereby obtaining a sintered body, (see, for example, Japanese Patent Application Laid-Open No. 2001-313427).

A p-type thermoelectric material may also be manufactured in the same manufacturing processes for an n-type thermoelectric material as mentioned above. The p-type thermoelectric material thus obtained has a figure of merit of about 3.0×10⁻³ K⁻¹.

However, in the n-type thermoelectric material obtained by sintering alloyed powder containing a material such as Bi, Te, Se, Sb or S, and a dopant in predetermined amounts at normal pressure, the increase in crystallite size or growth of crystallite proceeds, however, the densification of a sintered body does not proceed, failing to increase the density of the sintered body. Because of this, it is usually difficult to increase the power factor PF by increasing the mobility μ. In addition, the n-type thermoelectric material thus obtained has low mechanical strength. Therefore, it is virtually difficult to put such an n-type thermoelectric material into practical use.

In another n-type thermoelectric material obtained by subjecting alloyed powder containing a material such as Bi, Te, Se, Sb or S, and a dopant in predetermined amounts to hot-press sintering, since the growth of crystallite is inhibited, the crystallite is small, with the result that the mobility becomes low. Therefore, it is usually difficult to increase the power factor PF by increasing the mobility μ.

To summarize, when an n-type thermoelectric material is manufactured by sintering alloyed powder at the normal pressure sintering or hot-press sintering alone, it is difficult to increase the figure of merit Z by increasing the power factor PF. Therefore, the n-type thermoelectric material has a problem in that it is difficult to increase the figure of merit.

On the other hand, since a thermoelectric element is constructed of a p-type thermoelectric material and an n-type thermoelectric material in combination, the thermoelectric effect can be improved if p-type and n-type thermoelectric materials each having a high figure of merit are used. However, the figure of merit of the n-type thermoelectric material produced by the aforementioned process remains at most about 2.7×10⁻³ K⁻¹, which is lower than that of a p-type thermoelectric material. Because of this, it has been difficult to realize the thermoelectric element exhibiting a sufficient thermoelectric effect. Under these circumstances, it has been desired to further improve the figure of merit of an n-type thermoelectric material.

### SUMMARY OF THE INVENTION

It is an object of the present invention to at least solve the problems in the conventional technology.

A method of preparing an n-type thermoelectric material according to one aspect of the present invention includes mixing and melting a dopant to be added optionally and at least two elements selected from the group consisting of bismuth, tellurium, selenium, antimony, and sulfur to form a material mixture; cooling the material mixture to obtain an alloyed ingot; pulverizing the alloyed ingot to obtain pulverized powder; sintering the pulverized powder at normal pressure to obtain a half sintered body; and hot-pressing the half sintered body at pressure more than the normal pressure.

An n-type thermoelectric material according to another aspect of the present invention is prepared by the method according to the present invention.

The other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 is a flowchart of the manufacturing processes for an n-type thermoelectric material according to the present invention;

FIG. 2 is a table of the properties of the n-type thermoelectric materials obtained by the manufacturing processes of Example and Comparative Example of the present invention;

FIG. 3 is a graph of the relationship between the half-height width and the mobility with respect to the n-type thermoelectric materials obtained by the manufacturing processes of Example and Comparative Example of the present invention;

FIG. 4 is a table of the properties, power factor, and figure of merit with respect to the n-type thermoelectric materials obtained by the manufacturing processes of Example and Comparative Example of the present invention; and

FIG. 5 is a graph of the relationship between the half-height width and the figure of merit with respect to the n-type thermoelectric materials obtained by the manufacturing processes of Example and Comparative Example of the present invention.

### DETAILED DESCRIPTION

Exemplary embodiments of an n-type thermoelectric material and a method of preparing the n-type thermoelectric material relating to the present invention will be explained in detail below with reference to the accompanying drawings.

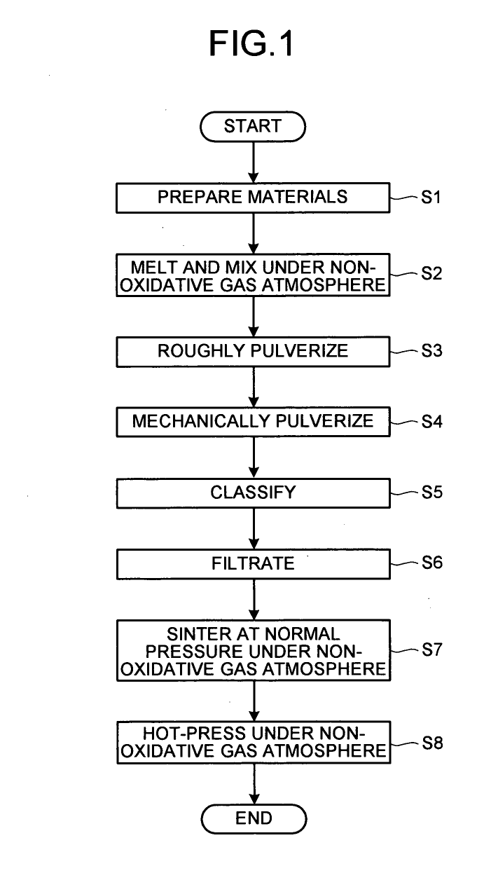

FIG. 1 is a flowchart of the procedure for manufacturing an n-type thermoelectric material according to an embodiment of the present invention.

As shown in FIG. 1, elements constituting a desired n-type thermoelectric material and a dopant to be added as an optional element are weighed out in predetermined amounts and mixed (step S1) to obtain a mixture. In the present invention, as the elements constituting an n-type thermoelectric material, use may be made of at least two elements selected from the group consisting of bismuth (Bi), tellurium (Te), selenium (Se), antimony (Sb), and sulfur (S). In addition, a dopant is added as needed in a predetermined amount in order to control and stabilize the carrier concentration of the n-type thermoelectric material.

Note that, as the dopant, use may be made of at least one selected from the group consisting of bismuth fluoride (BiF₃), bismuth chloride (BiCl₃), bismuth bromide (BiBr₃), bismuth iodide (Bil₃), tellurium chloride (TeCl₄) tellurium iodide (Tel₂, Tel₄), tellurium bromide (TeBr₄) selenium chloride (SeCl₄), selenium bromide (SeBr₄), selenium iodide (Sel₄), antimony fluoride (SbF₃), antimony chloride (SbCl₃, SbCl₅), and antimony bromide (SbBr₃).

In the next step, the mixture is heated to a temperature higher than the melting points of the raw materials under a non-oxidative gas atmosphere such as argon gas or a gas mixture containing argon gas and hydrogen gas, thereby melting the mixture (step S2). When Sb is contained as one of the raw materials, the mixture is melted at the temperature ranging from 670 degrees, centigrade to 720 degrees centigrade for 0.5 hour to 2 hours. After the raw materials are mixed while maintaining a melting state, the mixture is cooled to obtain an alloyed ingot.

The alloyed ingot thus obtained is then roughly pulverized in the presence of a solvent (step S3) and then mechanically pulverized in the presence of the solvent by a pulverization means such as a vibration mill (step S4) to prepare alloyed powder having particles of 1 micrometer to 10 micrometers in average.

As the solvent, hexane or a solvent represented by CₙH₂ₙ₊₁OH or CₙH₂ₙ₊₂CO (where n is 1, 2 or 3) may be used. Note that the solvent represented by CₙH₂ₙ₊₁OH or CₙH₂ₙ₊₂CO (where n is 1, 2 or 3) is methanol, ethanol, propanol, acetoaldehyde, acetone or methyl ethyl ketone.

Thereafter, the obtained pulverized powder is subjected classification through a stainless-steel sieve while being immersed in the solvent used during, the pulverization to prevent the powder from coming into contact with air as much as possible, thereby removing coarse particles and fine particles to obtain particles of a predetermined size or less (step S5). After the classification, the pulverized powder having particles of a predetermined size or less is filtrated (step S6).

The pulverized powder thus filtrated is subjected to the normal pressure sintering in the presence of the solvent (step S7). The normal pressure sintering is desirably performed under a non-oxidative atmosphere such as argon gas or a gas mixture containing argon gas and hydrogen gas and a temperature lower than the melting temperatures of the raw materials within the range from 500 degrees centigrade to 650 degrees centigrade. Note that it is satisfactory as long as it is possible to obtain a half sintered body having the crystallite sufficiently grown after the normal pressure sintering. In other words, it is not necessary to completely sinter the powder.

The half sintered body obtained in step S7 is subjected to hot-press sintering to completely sinter it (step S8). The hot-press sintering is desirably performed under a non-oxidative atmosphere such as argon gas or a gas mixture containing argon gas and hydrogen gas. The sintering temperature is desirably lower than the melting temperatures of the raw materials and not less than the sintering temperature employed in the normal pressure sintering within the range from 500 degrees centigrade to 650 degrees centigrade. Furthermore, the pressure used in the hot-press sintering is from 10 megapascals to 45 megapascals, preferably, 25 megapascals to 45 megapascals.

As explained above, the mobility of the n-type thermoelectric material is successfully increased for the first time by the process which includes subjecting pulverized alloyed power to the normal pressure sintering to obtain the half-sintered body and then subjecting the half sintered body to the hot-press sintering to completely sinter it. As a result, the power factor of the n-type thermoelectric material increases. Hence, the n-type thermoelectric material improved in figure of merit Z can be obtained.

In addition, the treatments in step S3 to S8 are performed within the solvent mentioned above. By virtue of this, oxygen absorption onto the pulverized alloyed powder is successfully suppressed, thereby preventing the solid-solution of oxygen in the n-type thermoelectric material obtained after sintering. As a result, the carrier density of the n-type thermoelectric material can be suppressed from increasing and instead, the mobility increases, contributing an increase of the power factor. Therefore, it is possible to obtain an n-type thermoelectric material further improved in figure of merit Z.

The sintered body of the n-type thermoelectric material thus obtained may be a solid solution formed of bismuth telluride (Bi₂Te₃), bismuth selenide (Bi₂Se₃), antimony telluride (Sb₂Te₃), antimony selenide (Sb₂Se₃), bismuth sulfide (Bi₂S₃), or antimony sulfide (Sb₂S) or a combination of these.

### EXAMPLES

The present invention will now be described in detail below by way of Examples.

Flakes of Te, Bi and Se (all are high-purity grade reagent with a purity of 4N (99.99%)) were weighed out so as to obtain an alloyed ingot containing bismuth telluride (Bi₂Te₃) and bismuth selenide (Bi₂Se₃) in a molar ratio of 95:5. As a dopant, a predetermined amount of tellurium iodide (Tel₄) was weighed out. These materials were placed in a graphite crucible, melted and mixed by heating at 720 degrees centigrade in the gas mixture containing argon gas (97%) and hydrogen gas (3%), and then allowed to stand in a natural state to cool to near room temperature. In this manner, an alloyed ingot having a desired composition was obtained.

The alloyed ingot was roughly pulverized while immersing it in a solvent, n-hexane, and mechanically pulverized by a vibration mill into pulverized powder. Thereafter, the pulverized power was classified by a sieve to obtain powder having particles of a predetermined size or less. The obtained powder was then filtrated to obtain powder having particles of virtually the same size (about 6 micrometers in average).

Thereafter, the obtained powder was immersed in a solvent, n-hexane, and sintered at 590 degrees centigrade and normal pressure under a mixed gas atmosphere containing argon gas (97%) and hydrogen gas (3%) to obtain a half-sintered body. The half-sintered body was further subjected to hot-press sintering performed at 590 degrees centigrade while pressurizing it at 45 megapascals under a mixed gas atmosphere containing argon gas (97%) and hydrogen gas (3%) to obtain a sintered body.

On the other hand, in Comparative Example, the alloyed ingot of the aforementioned composition allowed to cool in a natural state to near room temperature was pulverized in the same method as in Example, and immersing it in a solvent, n-hexane, and then subjected to the hot-press sintering performed at 590 degrees centigrade under a mixed gas atmosphere containing argon gas (97%) and hydrogen gas (3%) while pressurizing it at 45 megapascals.

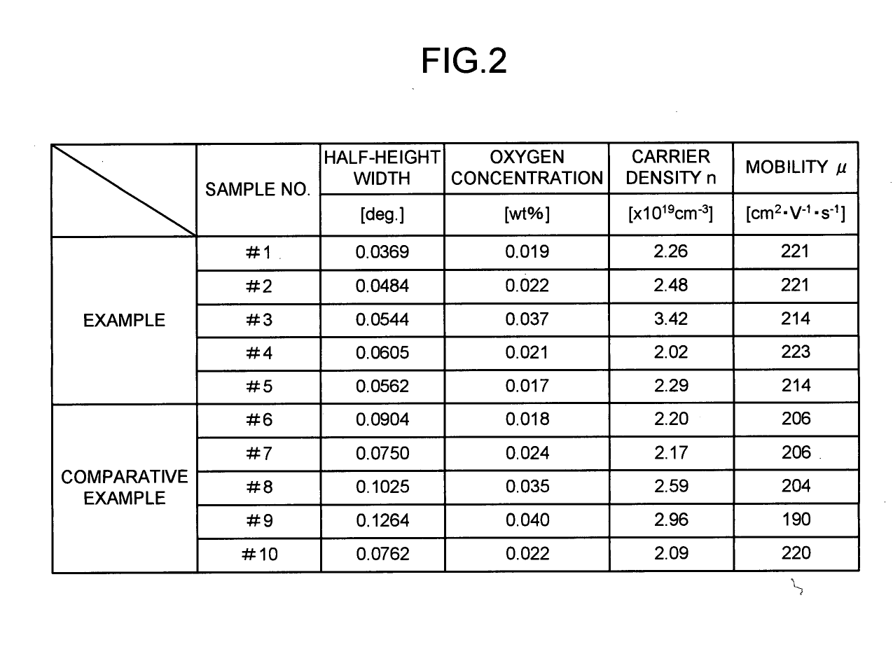

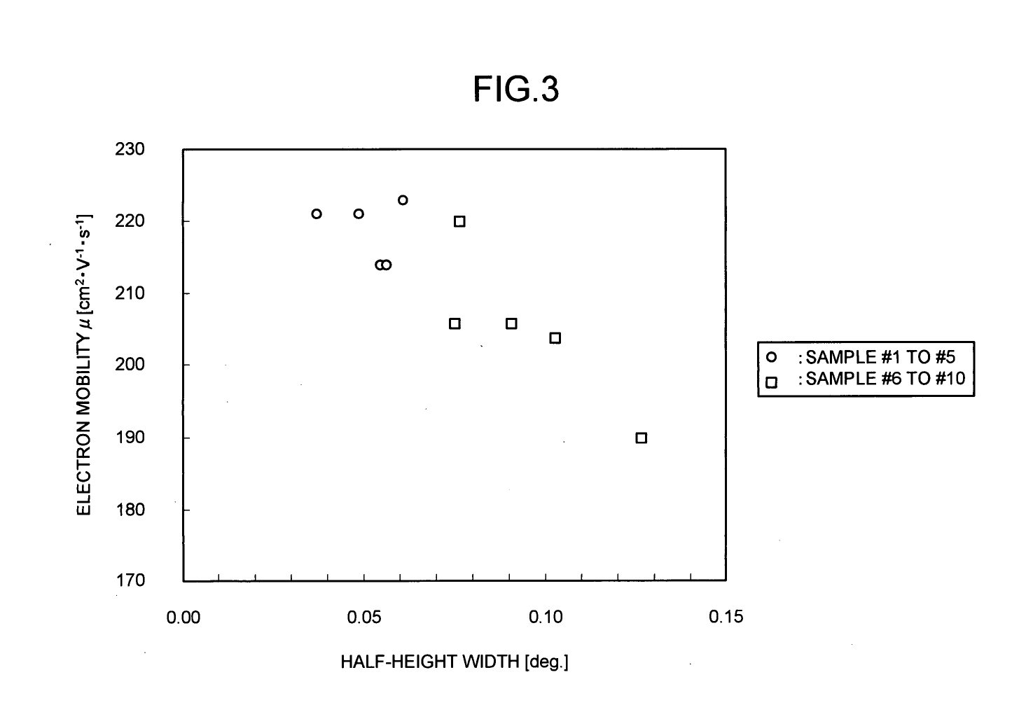

After the sintered body of an n-type thermoelectric material thus obtained was processed into an arbitrary shape, it was measured for the half-height width, oxygen concentration, carrier density and mobility. FIG. 2 is a table of the measurement results (half-height width, oxygen concentration, carrier density, and mobility) with respect to sintered bodies (#1 to #5) of Example, and sintered bodies (#6 to #10) of Comparative Example. FIG. 3 is a graph of the relation between the half-height width and the electron mobility shown in FIG. 2.

The half-height width of FIG. 2 is the average of the values obtained by subtracting the half-height width intrinsic to an X-ray diffraction apparatus from diffraction-peak half-height width measurement values with respect to three (00I) planes, namely, (0015), (0018) and (0021) planes, obtained by X-ray diffraction. The three (00I) planes of the sintered sample are perpendicular to the direction of applying hot-press sintering. More specifically, assuming that peak half-height width measurement values of the (00I) plane are A₀₀₁₅, A₀₀₁₈, and A₀₀₂₁, and the half-height width intrinsic to the X-ray diffraction apparatus is B, half-height width A shown in FIG. 2 can be obtained by the following equation (3):

A=[(A₀₀₁₅²−B²)^{1/2}+(A₀₀₁₈²−B²)^{1/2}]/3 (3)

Note that each of the diffraction-peak half-height width values of the (00I) plane was measured by the X-ray diffraction apparatus of RU-200 type (manufactured by Rigaku Corporation) while applying CuKα ray within the range of an angle 2θ from 5 degrees to 80 degrees. The tube voltage and the tube current used in the measurement were 40 kilovolts and 150 milliamperes, respectively.

On the other hand, the oxygen concentration shown in FIG. 2 was measured as follows. A sample was weighted out in a predetermined amount, placed in an Ni capsule, and melted in a carbon crucible while supplying helium gas. Oxygen gas released from the sample during the melting was supplied to a carbon catalyst layer to obtain carbon monoxide, the amount of which was measured by an infrared radiation absorption method.

As is apparent from FIG. 2, the n-type thermoelectric materials (sample #6 to #10) formed by the process of Comparative Example have large half-height width and small mobility compared to those (sample #1 to #5) formed by the process of Example, although the oxygen concentrations are virtually equal. It is generally known that the larger the half-height width of the diffraction peak detected by the X-ray diffraction analysis, the smaller the size of the crystallite. From these facts, it is considered the reason why the mobility of electrons within the crystal is decreased is that the size of the crystallite constituting each of the materials of sample #6 to #10 is small. This is considered due to sintering of samples #6 to #10 in hot-press sintering process alone, with the result that the growth of crystallite is inhibited during the hot-press sintering.

In contrast, the n-type thermoelectric materials (sample #1 to #5) formed by the process of Example have a relatively small half-height width of not more than 0.07 degree, compared to those (sample #6 to #10) formed by the process for Comparative Example and have substantially the same mobility. More specifically, in the n-type thermoelectric materials of samples #1 to #5, the mobility of electrons within a crystal is increased by increasing the size of crystallite. This is attained by subjecting samples #1 to #5 to the normal pressure sintering, thereby accelerating the growth of crystallite, and then subjecting it to the hot-press sintering, thereby accelerating the densification of a sintered body to increase the density thereof, with the result that a decrease of the mobility caused by reducing the size of crystallite is prevented.

It is therefore demonstrated that the manufacturing process of the present invention makes it possible to provide an n-type thermoelectric material having large crystallite which decreases the half-height width and increase the mobility.

As is seen in FIG. 3 of the relationship between the half-height width and mobility, the mobility increases as the half-height width decreases.

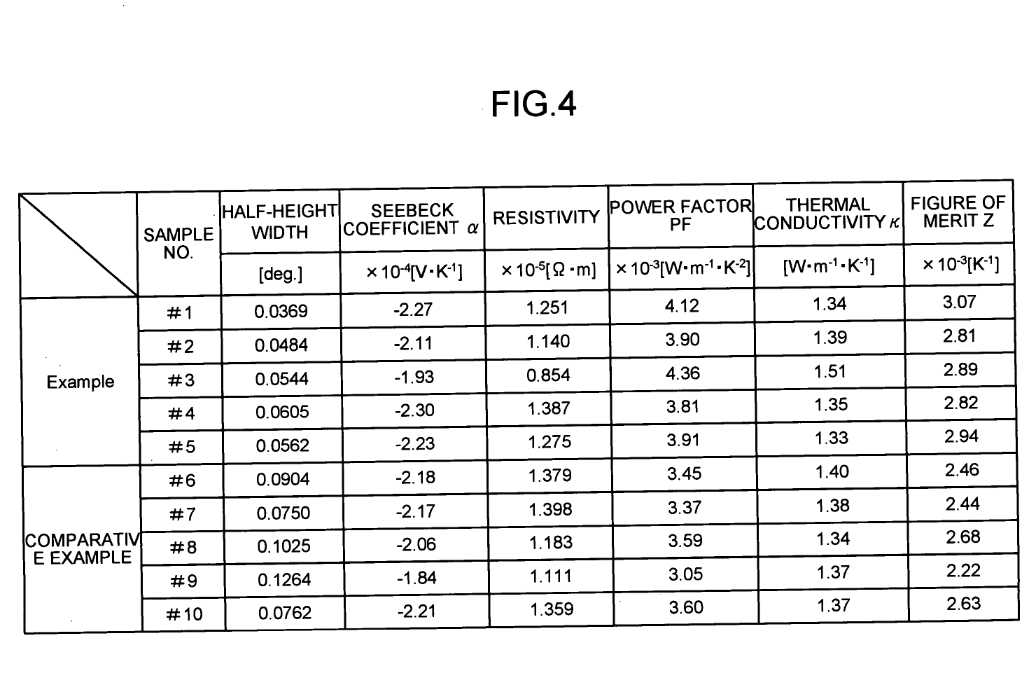

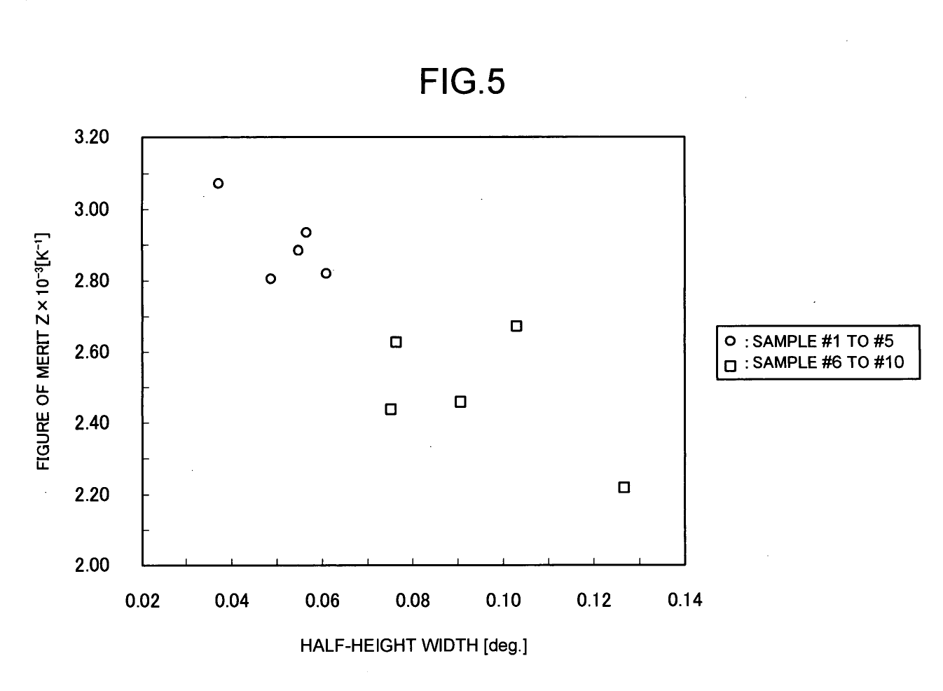

On the other hand, FIG. 4 is a table of the measurement results of half-height width, the Seebeck coefficient, the resistivity, thermal conductivity, power factor, and the figure of merit with respect to n-type thermoelectric materials #1 to #5 according to Example and #6 to #10 according to Comparative Example. FIG. 5 is a graph of the relation between the half-height width and the figure of merit of FIG. 4.

As is apparent from FIG. 4, samples #1 to #5 of Example have large power factor and figure of merit compared to samples #6 to #10 of Comparative Example. This is considered as follows. The fact that samples #1 to #5 (obtained by a manufacturing process of the present invention) have small half-height width means that the crystallite is large. Because of this, the mobility within the crystal increases, increasing the power factor. As a result, the figure of merit is considered to increase since it has in a proportional relationship with the power factor.

In brief, according to the n-type thermoelectric material obtained by the method of the present invention, it is possible to improve the performance represented by the figure of merit by increasing the size of crystallite, in other words, decreasing the half-height width.

As is apparent from FIG. 5, as the half-height width decreases, the figure of merit increases. More specifically, if the half-height width is set at not more than 0.07 degree, the figure of merit can be greatly improved to 2.8×10⁻³ K⁻¹ or more.

In Example, n-hexane is used as a solvent. Even in the case where a solvent represented by CₙH₂ₙ₊₁OH or CₙH₂ₙ₊₂CO (where n is 1, 2 or 3) is used, the power factor was improved by decreasing the half-height width. Furthermore, even in the case where an alloy except an alloy containing bismuth telluride (Bi₂Te₃) and bismuth selenide (Bi₂Se₃) in a molar ratio of 95:5 is pulverized in a solvent such as n-hexane or a solvent represented by CₙH₂ₙ₊₁OH or CₙH₂ₙ₊₂CO (where n is 1, 2 or 3), and subjected to the normal pressure sintering and hot-press sintering, the power factor was improved by decreasing the half-height width.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of preparing an n-type thermoelectric material, comprising:
mixing and melting a dopant to be added optionally and at least two elements selected from the group consisting of bismuth, tellurium, selenium, antimony, and sulfur to form a material mixture;
cooling the material mixture to obtain an alloyed ingot;
pulverizing the alloyed ingot to obtain pulverized powder;
sintering the pulverized powder at normal pressure to obtain a half sintered body; and
hot-pressing the half sintered body at pressure more than the normal pressure.

2. The method according to claim 1, wherein the sintering includes baking the pulverized powder at a sintering temperature of from 500 degrees centigrade to 650 degrees centigrade.

3. The method according to claim 1, wherein the hot-pressing includes hot-pressing at a sintering temperature of from 500 degrees centigrade to 650 degrees centigrade while pressurizing at a pressure of from 10 megapascals to 45 megapascals.

4. The method according to claim 1, wherein the hot-pressing includes hot-pressing at a sintering temperature that is not less than a temperature employed in sintering the pulverized powder.

5. The method according to claim 1, wherein an average particle diameter of the pulverized power is 1 micrometer to 10 micrometers.

6. The method according to claim 1, wherein, each of the pulverizing, the sintering, and the hot-pressing is performed in a solvent selected from the group consisting of hexane, CₙH₂ₙ₊₁OH, and CₙH₂ₙ₊₂CO, where n is an integer of 1 to 3.

7. The method according to claim 1, wherein each of the sintering and the hot-pressing is performed under a non-oxidative gas atmosphere.

8. An n-type thermoelectric material prepared by a process which comprises:
mixing and melting a dopant to be added optionally and at least two elements selected from the group consisting of bismuth, tellurium, selenium, antimony, and sulfur to form a material mixture;
cooling the material mixture to obtain an alloyed ingot;
pulverizing the alloyed ingot to obtain pulverized powder;
sintering the pulverized powder at normal pressure to obtain a half sintered body; and
hot-pressing the half sintered body at pressure more than the normal pressure.

9. The n-type thermoelectric material according to claim 8, wherein
an average half-height width of each of at least three (00I) planes of the n-type thermoelectric material is not more than 0.07 degree,
the average half-height width is obtained by subtracting a half-height width intrinsic to an X-ray diffraction apparatus from diffraction-peak half-height width measurement values obtained by an X-ray diffraction analysis with respect to the at least three (00I) planes where I is an integer, and
the X-ray diffraction analysis is performed for planes being in perpendicular to a direction of applying the hot press.

10. The n-type thermoelectric material according to claim 9, wherein the at least three (00I) planes are a (0015) plane, a (0018) plane, and a (0021) plane, respectively.
